(19) United States
(12) Patent Application Publication
(10) Pub. No.: US 2026/0223321 A1
(43) Pub. Date: Jul. 30, 2026

(54) ASSEMBLIES FOR FACILITATING HEAT TRANSFER

(71) Applicant: Toyota Motor Engineering & Manufacturing North America, Inc., Plano, TX (US)

(72) Inventor: Shailesh N. Joshi, Ann Arbor, MI (US)

(73) Assignee: Toyota Motor Engineering & Manufacturing North America, Inc., Plano, TX (US)

(21) Appl. No.: 19/040,308

(22) Filed: Jan. 29, 2025

(51) Int. Cl. H05K 7/20

(52) U.S. Cl. CPC H05K 7/20272

(57) ABSTRACT

An assembly for facilitating heat transfer includes a single-phase cooler having a liquid chamber with a plurality of micro-channels therein. The assembly includes a liquid in the liquid chamber. The assembly includes a plurality of particles in the liquid, the plurality of particles configured to self-propel by thermophoresis such that the plurality of particles are self-propelled at a temperature difference between a free-flowing layer and a viscous sublayer of the liquid within the liquid chamber. The self-propelled movement of the plurality of particles mixes the liquid and causes the boundary between the free flowing layer and the viscous sublayer to be disrupted.

### TECHNICAL FIELD

The present specification generally relates to cooler apparatuses for regulating a temperature of a component and, more specifically, to single-phase coolers for removing heat from power electronic devices.

### BACKGROUND

Powered electronic devices, e.g., multi-layered printed circuit board (PCB) assemblies having metal-oxide-semiconductor field-effect transistors (MOSFETs) or the like, typically generate heat during operation. Powered electric devices typically also have a maximum operating temperature, i.e., a temperature that may damage or otherwise adversely impact operation of the powered electronic device. Liquid based single-phase cooler assemblies have been used to regulate the operating temperature of powered electronic devices thermal coupled thereto.

A need exists for alternative cooler assemblies for regulating a temperature of a powered electric device that provide increases operational efficiency and heat transfer performance relative to current designs of single-phase coolers for removing heat from power electronic devices.

### SUMMARY

In one embodiment, an assembly for facilitating heat transfer may include a single-phase cooler having a liquid chamber with a plurality of micro-channels therein. The assembly includes a liquid in the liquid chamber. The assembly includes a plurality of particles in the liquid, the plurality of particles configured to self-propel by thermophoresis such that the plurality of particles are self-propelled at a temperature difference between a free-flowing layer and a viscous sublayer of the liquid within the liquid chamber. Self-propelled movement of the plurality of particles mixes the liquid and causes the boundary between the free flowing layer and the viscous sublayer to be disrupted.

In one embodiment, an assembly for facilitating heat transfer may include a cooler having a liquid chamber. The assembly includes a liquid in the liquid chamber. The assembly includes a plurality of particles in the liquid, the plurality of particles configured to self-propel within the liquid.

In another embodiment, a system for facilitating heat transfer includes a pump and a cooler having a liquid chamber fluidly coupled to the pump. The system includes a liquid in the liquid chamber. The system includes a plurality of particles in the liquid, the plurality of particles configured to self-propel within the liquid.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view an assembly and a component, the assembly facilitating transfer of heat away from the component and according to one or more embodiments shown and described herein;

FIG. 2 schematically depicts a diagram of a system including the assembly of FIG. 1 for facilitating heat transfer, according to one or more embodiments shown and described herein;

FIG. 3 schematically depicts a cross-section of the assembly taken along the line 3-3 shown in FIG. 1, according to one or more embodiments shown and described herein;

FIG. 4A schematically depicts particles disposed in a liquid of the assembly prior to self-propelled movement of the particles, according to one or more embodiments shown and described herein;

FIG. 4B schematically depicts the particles disposed in the liquid of the assembly after self-propelled movement of the particles, according to one or more embodiments shown and described herein; and

FIG. 5 schematically depicts an isolated view of one of the particles disposed in the liquid of FIG. 4A and/or FIG. 4B, according to one or more embodiments shown and described herein.

### DETAILED DESCRIPTION

Embodiments described herein are directed to an assembly for facilitating heat transfer, e.g., away from a powered electronics component. The assembly includes a cooler having a liquid chamber. The assembly includes a liquid in the liquid chamber and a plurality of particles in the liquid. The plurality of particles are configured to self-propel within the liquid based on self-thermophoresis. The plurality of particles are tuned to move around a viscous layer boundary in a warmed fluid to disrupt the viscous layer boundary and enhance cooling compared to conventional systems. That is, in conventional systems, there is a viscous sublayer that is formed by a heat flux generated by a heat-generating component (e.g., the powered electronics component). Viscous sublayers, which are also referred to as laminar boundary layers, are a thin layer in the immediate vicinity of a bounding surface formed by fluid flowing along the surface. Viscous sublayers may prevent the free-flow of liquid, causing higher thermal resistance and inhibiting heat flux removal capability. Accordingly, the movement of each of the plurality of particles disrupt or otherwise break apart the any formed viscous sublayers, which provides for a more consistent free-flow of liquid and improved heat flux removal compared to conventional systems.

Embodiments described herein are directed to a system for facilitating heat transfer, e.g., away from a powered electronics component. The system includes a pump and a cooler having a liquid chamber fluidly coupled to the pump. The system includes a liquid in the liquid chamber and a plurality of particles in the liquid. The plurality of are particles configured to self-propel within the liquid.

The plurality of particles configured to self-propel within the liquid may increase heat transfer efficiency of the assembly and system. For example, and without limitation, the particles may self-propel from a warmer area of the liquid to a cooler area and thereby transfer heat from to warmer area to the cooler area. As another example, and without limitation, the particles configured to self-propel may disrupt a barrier between a freestream area of the liquid and a viscus sublayer of the liquid to transfer heat from the viscus sublayer to the freestream.

Whenever possible, the same reference numerals will be used throughout the drawings to refer to the same or like parts.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

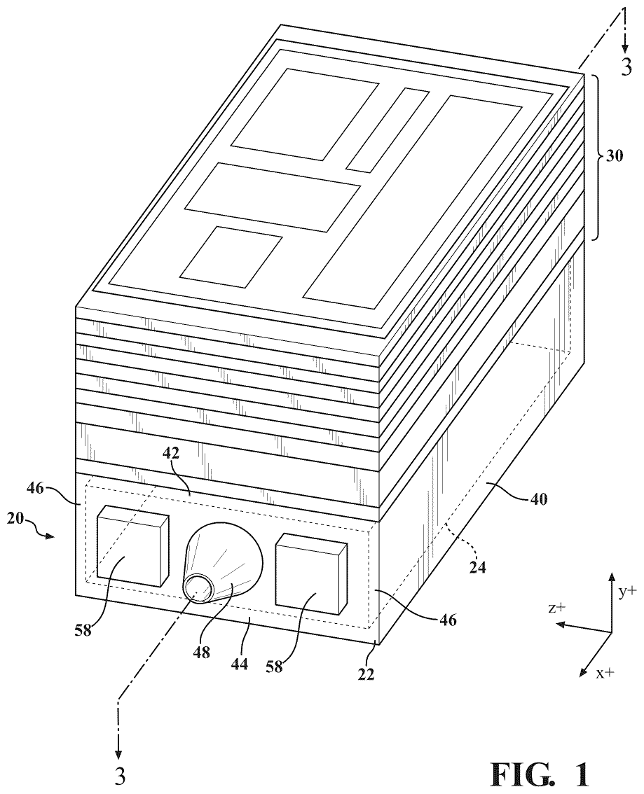

As used herein, the term “longitudinal direction” refers to the forward-rearward direction of the assembly (i.e., in the +/−X-direction depicted in FIG. 1). The term “lateral direction” refers to the cross-assembly direction (i.e., in the +/−Z-direction depicted in FIG. 1), and is transverse to the longitudinal direction. The term “vertical direction” or “up” or “bottom” or “below” refer to the upward-downward direction of the assembly (i.e., in the +/−Y-direction depicted in FIG. 1). That is, the terms “top” and “bottom” refers to the upward-downward direction of the assembly (i.e., in the +/−Y direction of the coordinate axes depicted in FIG. 1). As used herein, “top” is defined as generally being towards the positive Y direction of the coordinate axes shown in the drawings. “Below” is defined as generally being towards the negative Y direction of the coordinate axes shown in the drawings.

It should be understood that directional terms as used herein-for example up, down, right, left, front, back, top, bottom-are made only with reference to the figures as drawn and are not intended to imply absolute orientation.

As used herein, the singular forms “a,” “an” and “the” include plural referents unless the context clearly dictates otherwise. Thus, for example, reference to “a” component includes aspects having two or more such components, unless the context clearly indicates otherwise.

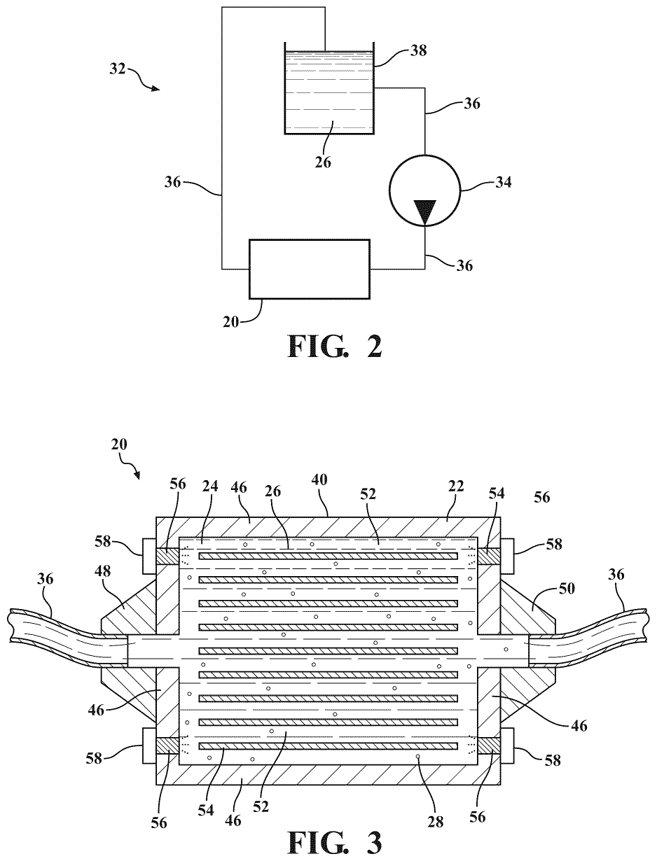

Now referring to FIGS. 1-3, an example assembly 20 for facilitating heat transfer is schematically depicted. The example assembly 20 includes a cooler 22 having a liquid chamber 24. A liquid 26 is disposed in the liquid chamber 24, and a plurality of particles 28 are disposed in the liquid 26. The plurality of particles 28 are configured to self-propel within the liquid 26, e.g., in response to a temperature of the liquid 26 exceeding a certain threshold and/or in response to application of radiant energy to the particles 28 and as further discussed below. The assembly 20 facilities heat transfer away from the cooler 22 via flow of the liquid 26, e.g., into and out of the cooler 22. Movement of the particles 28 within the liquid 26 facilities heat transfer from the cooler 22 to the liquid 26. The assembly 20 may be included in an example liquid thermal management system 32 (shown in FIG. 2) for facilitating heat transfer. The example liquid thermal management system 32 may include a liquid pump 34 and a liquid reservoir 38 fluidly coupled to the assembly 20, e.g., via tubing 36, pipe, or other fluid conduit.

With reference to FIGS. 1 and 3, the cooler 22 is included in the assembly 20 to absorb heat energy, e.g., from a component 30 that is thermally coupled to the cooler 22, and transfer such energy to the liquid 26. The component 30 may be a power electronics device that includes one or more insulated-gate bipolar transistors (IGBTs), one or more metal-oxide- semiconductor field-effect transistors (MOSFETs), and the like. For example, and without limitation, the component 30 may be a multi-layer printed circuit board (PCB) assembly that includes semiconductors, control/drive/protection electronic circuitry, power devices, and/or passive components, embedded therein. The multi-layer PCB may include a plurality of dielectric layers and a plurality of power layers. The power layers may include a dielectric material and a conductive material. The dielectric layers may include the dielectric material and conductive vias that provide electrical communication or pathways between adjacent power layers. Stated differently, the power layers may include conductive (e.g., copper) patterns and the dielectric layers may include conductive (e.g., copper) pathways that connect the conductive patterns such that the multi-layer PCB functions and/or operates as desired. Operation of the component 30 may generate heat that should be removed, e.g., to maintain a temperature of the component 30 below a maximum operating temperature.

The cooler 22 may be thermally coupled to the component 30 such that heat from the component 30 can flow to the cooler 22. For example, and without limitation, the component 30 may be directly attached to a top surface of the cooler 22, e.g., with a bonding interface (not shown). The bonding interface may include a low thermal resistance (LTR) dielectric layer disposed between the component 30 and the cooler 22. In other variations, the bonding interface may include a chemical vapor deposition (CVD) dielectric layer disposed between the component 30 and the cooler 22. In still other variations, the bonding interface may include a ceramic sintered layer disposed between the component 30 and the cooler 22. In other variations, the bonding interface may include a solder layer, solder-AlN-solder layers, and/or solder-Si3N4-solder layers. And in at least one variation the bonding interface is one or more 3D printed dielectric layers disposed between the component 30 and the cooler 22, e.g., one or more polymer-conductive filler composite layers.

The cooler 22 may be any suitable single-phase liquid cooler. In other words, the cooler 22 may utilize liquid that maintains a single-phase, i.e., the liquid phase, as a heat transfer medium. That is, during operation of the cooler 22, the liquid 26 does not undergo phase change, e.g., to a gas. The liquid 26 in the liquid chamber 24 is provided to absorb heat from the cooler 22. For example, the liquid 26 may be a dielectric liquid, water, or any suitable liquid. Example dielectric liquids include, but are not limited to mineral oil, n-Hexane, n-Heptane, castor oil natural ester, refined and dried castor oil, Hatcol 5005 synthetic ester, silicone oil, fluorinert FC-72, Novec 649, Novec 7100, polychlorinated biphenyls, purified water, liquid nitrogen, liquid helium, liquid argon, etc.

The cooler 22 may include a main body 40 that defines the liquid chamber 24. In other words, the cooler 22 may be hollow with the liquid chamber 24 therein. For example, and without limitation, the main body 40 may include a top wall 42, a bottom wall 44, and sidewalls 46 extending from the top wall 42 to the bottom wall 44. The top wall 42, the bottom wall 44, and the sidewalls 46 may surround and generally enclose or define the liquid chamber 24. The cooler 22 may be generally rectangular, or any suitable shape, for example and without limitation, circular, square, hexagonal, octagonal, elliptical, and the like. The main body 40 may be is formed of a material having a generally high thermal conductivity, such as, and without limitation, aluminum, copper, metal alloys, and/or the like.

The cooler 22, e.g., the main body 40, may include an inlet port 48 and an outlet port 50 for facilitating liquid flow into and out of the liquid chamber 24, respectively. In the depicted embodiment of FIG. 3, the inlet port 48 is disposed at one of the sidewalls 46 and the outlet port 50 is disposed in another of the sidewalls 46 opposite the inlet port 48. However, this is not limiting. The inlet port 48 and the outlet port 50 may extend completely through the sidewalls 46, i.e., from external of the main body 40 to the liquid chamber 24. The main body 40 may include more than one of each the inlet port 48 and the outlet port 50, e.g., two, three, etc. Additionally or alternately to being located at opposite sidewalls 46, one or more inlet ports 48 and/or one or more outlet ports 50 may be located at adjacent sidewall 46, the top wall 42, and/or the bottom wall 44. The tubing 36, pipe, or other fluid conduit connecting the assembly 20 to other components of the liquid thermal management system 32 may be coupled to the inlet port 48 and the outlet port 50 to provide fluid communication with the liquid chamber 24 of the cooler 22.

With reference to FIG. 3, the liquid chamber 24 of the cooler 22 may include micro-channels 52. The liquid 26 with particles 28 therein may be in micro-channels 52, e.g., as the liquid 26 flows through the liquid chamber 24. The micro-channels 52 increase an amount of surface area of the cooler 22 in contact with the liquid 26 in the liquid chamber 24. The increased amount of surface area increases a rate of heat transfer between the liquid 26 and the cooler 22, e.g., as compared to without the micro-channels 52. The micro-channels 52 may be defined, for example, and without limitation, by a plurality of internal walls 54 elongated within the liquid chamber 24 from proximate the sidewall 46 having the inlet port 48 to proximate the sidewall 46 having the outlet port 50. Distal ends of the internal walls 54 may be spaced from the sidewalls 46 having the inlet port 48 and the outlet port 50. The micro-channels 52 may have any other suitable shape permitting liquid 26 flow from the inlet port 48 to the outlet port 50 and increasing surface area in contact with the liquid 26 to increase heat transfer.

The cooler 22 may include one or more windows 56 that permit radiant energy, e.g., light, to enter the liquid chamber 24. The one or more windows 56 are formed of transparent or semi-transparent glass, high temperature plastic, or other suitable material that can withstand operational temperatures of the cooler 22 and allow a sufficient amount of radiant energy to enter the liquid chamber 24 to cause motion of the particles 28, as discussed below. The windows 56 may be located, for example, and without limitation, the sidewalls 46 (as shown), the top wall 42, and/or the bottom wall 44. The light wavelength fall within the visible spectrum.

The assembly 20 may include a radiant energy emitter 58 configured to emit radiant energy, e.g., light. The radiant energy emitter 58 converts electric energy into radiant energy. The radiant energy emitter 58 may be, for example, and without limitation, a light emitting diode (LED), a laser, or other suitable structure. The radiant energy emitter 58 may be configured to emit radiant energy into the liquid chamber 24. Emitting radiant energy into the liquid chamber 24 provides radiant energy to the particles 28 and may induce self-propulsion, e.g., as discussed below. The radiant energy emitter 58 may be configured to emit radiant energy into the liquid chamber 24 through the window 56. For example, and without limitation, the radiant energy emitter 58 may be attached to the cooler 22 at the window 56, e.g., via adhesive, fastener, etc., and may be oriented such that radiant energy emitted by the radiant energy emitter 58 is directed at, and though, the window 56 into the liquid chamber 24. The radiant energy emitter 58 may be supported by other suitable structure and/or be in any other suitable orientation such that energy emitted by the radiant energy emitter 58 is provided to the particles 28 in the liquid 26 within the cooler 22, e.g., at a viscous sublayer 60 of the liquid 26 with the liquid chamber 24 and/or at a border 62 between the viscous sublayer 60 and a freestream 64 of the liquid 26 in the liquid chamber 24, as further discussed below.

With reference to FIG. 2, the example liquid thermal management system 32 circulates the liquid 26 through the assembly 20. The liquid pump 34 of liquid thermal management system 32 may be fluidly coupled to the assembly 20, i.e., such that liquid 26 urged by the pump 34 is directed to the assembly 20. The pump 34 may be a lobe pump, a vibration pump, a centrifugal pump, a piston and cylinder pump, or any suitable type. The liquid pump 34 may be fluidly coupled to the assembly 20, for example, and without limitation, via tubing 36, pipe, or other fluid conduit connecting the liquid pump 34 to the assembly 20. The liquid reservoir 38 of the liquid thermal management system 32 may be fluidly coupled to the pump 34 and the assembly 20, i.e., such that the pump 34 can urge liquid 26 from the liquid reservoir 38 to the assembly 20. As such, the liquid pump 34, the reservoir 38 and the assembly 20 may be in fluid communication, e.g., with the liquid pump 34 downstream from the reservoir 38, and the assembly 20 downstream of the liquid pump 34 and upstream of the reservoir 38.

The liquid reservoir 38 may be a tank or other container configured for storing the liquid 26 to be circulated through the assembly 20. Tubing 36, pipe, or other fluid conduit may connect the liquid reservoir 38 to the pump 34. The pump 34, the assembly 20, and the liquid reservoir 38 may be connected in a closed loop system, e.g., such that the pump 34 urges the liquid 26 from the liquid reservoir 38 to the assembly 20, and from the assembly 20 back to the liquid reservoir 38. The example liquid thermal management system 32 may include other structures, e.g., a radiator, heat exchanger, or the like, to remove heat energy from the liquid 26. The liquid thermal management system 32 may be arranged other than as shown. For example, and without limitation, the pump 34 may be upstream of the liquid reservoir 38 and urge liquid 26 from the liquid reservoir 38 to the assembly 20 by inducing a positive pressure in the liquid reservoir 38.

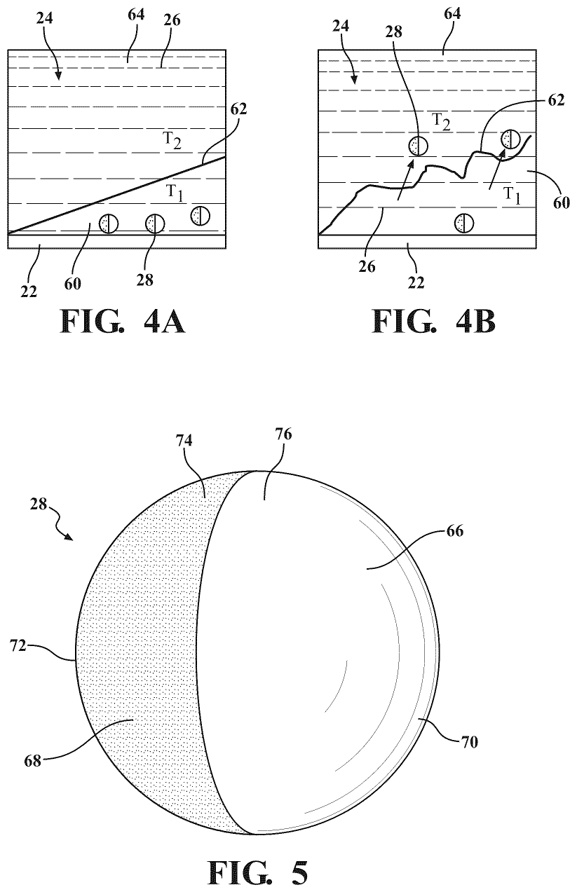

With reference to FIG. 4A, the liquid 26 flowing through the liquid chamber 24 defines the viscous sublayer 60 and the freestream 64. The viscous sublayer 60 is a region of a mainly-turbulent flow of the liquid 26, e.g., caused by flow velocity decreases at a no slip boundary of the internal surfaces of the sidewalls 46, the top wall 42, and the bottom wall 44, and the surfaces of one or more of the internal walls 54. Accordingly, the viscous sublayer 60 abuts one or more of the internal surfaces of the cooler 22, e.g., between the freestream 64 and the one or more internal surfaces of the sidewalls 46, the top wall 42, and the bottom wall 44. The freestream 64 is spaced from one or more internal surfaces of the cooler 22 that provide the no slip boundary to the liquid 26 flowing through the cooler 22, e.g., surfaces of the internal walls 54, internal surfaces of the sidewalls 46, the top wall 42, and/or the bottom wall 44. The viscous sublayer 60 is between the freestream 64 and the one or more internal surfaces of the cooler 22 that provide the no slip boundary to the liquid 26 flowing through the cooler 22.

A first temperature T1 of the liquid 26 in the viscous sublayer 60 may be higher, or greater than, a second temperature T2 of the liquid 26 in the freestream 64. During operation, the cooler 22 may have a higher temperature than the liquid 26, e.g., due to the cooler 64 absorbing heat from the component 30. Heat from the cooler 22 may be absorbed by the liquid 26 in the viscous sublayer 60 to heat the liquid 26 in the viscous sublayer 60 to the first temperature T1. Heat from the viscous sublayer 60 heated to the first temperature T1 may be then absorbed by the liquid 26 in the freestream 64 to heat the liquid 26 in the freestream 64 to the second temperature T2. The heat flow direction (e.g., from the cooler 22 to the viscous sublayer 60 and then to the freestream 64) and the liquid 26 in the freestream 64 flowing though the cooler 22 faster than the liquid 26 in the viscous sublayer 60 causes the first temperature T1 of the liquid 26 in the viscous sublayer 60 to be higher than the second temperature T2 of the liquid 26 in the freestream. The differential between the first temperature T1 of the liquid 26 in the viscous sublayer 60 and the second temperature T2 of the liquid 26 in the freestream 64 may cause the particles 28 to self-propel, e.g., from the viscous sublayer 60 and toward the freestream 64 and as further discussed below.

With reference to FIG. 4B, the particles 28 may mix or otherwise agitate the liquid 26 upon self-propulsion. For example, and without limitation, self-propulsion of one or more of the particles 28 within the viscous sublayer 60 of the liquid 26 may cause such particles to move into, or at least toward, the freestream 64 of the liquid 26 and may cause the liquid 26 of the viscous sublayer 60 to mix with liquid 26 of the free stream. Such movement may increase heat transfer from the viscous sublayer 60 to the freestream 64 to be more readily removed from the cooler 22. For example, self-propelled movement of the particles 28 may generate small eddy currents that disrupt the border 62 between the viscous sublayer and the freestream 64, e.g., as schematically shown in a comparison of FIGS. 4A and 4B. The warmer liquid 26 of the viscous sublayer 60 may enter the cooler liquid 26 of the freestream 64 at the disrupted border 62. The cooler liquid 26 of the freestream 64 at the disrupted border 62 may enter the warmer viscous sublayer 60 to replace to liquid 26 moving from the viscous sublayer 60 to the freestream 64.

With reference to FIG. 5, the particles 28 may be, for example, and without limitation, Janus particles. Janus particles are nanoparticles or microparticles whose surfaces have two or more distinct physical properties. For example, and without limitation, one-half of the surface of the particle may be composed of hydrophilic material and the other half of the surface composed of hydrophobic material. As another example, and without limitation, a first portion 66 and a second portion 68 of each particle may have different thermal properties. The different thermal properties may cause localized temperature variations in the liquid 26, e.g., proximate the first portions 66 and the second portions 68 of the particles 28. The different thermal properties may cause the liquid 26 proximate the first portion 66 to have a lower temperature relative to the liquid 26 proximate the second portion 68. Such differences in temperature may urge the particles 28 to propel within the liquid 26, e.g., along a direction that generally extends from the second portion 68 toward the first portion 66. The particles 28 may be, of example, about 10 μm to 53 μm in diameter.

The plurality of particles 28 are configured to self-propel within the fluid without a chemical reaction. In other words, the particles 28 self-propel without undergoing a change to their chemical structure. Propulsion without chemical change enables relatively longer operational life of the particles 28. In other words, particles that self-propel via chemical reaction may be limited in their operational life, e.g., until a compound of such particle that undergoes the chemical reaction is depleted.

The plurality of particles 28 may be configured to self-propel by thermophoresis. In other words, the particles 28 may self-propel in response to thermophoretic forces generated in a temperature gradient of the liquid 26, e.g., in a temperature gradient at the border 62 between the freestream 64 and the viscous sublayer 60 of the liquid 26. For example, and without limitation, the particles 28 may be configured to self-propel within the liquid 26 due to the Soret effect (or the Ludwig-Soret effect). The particles 28 may have different materials and/or coating for the first portions 66 and the second portions 68 to provide different heat conductivity and heat absorption characteristics to the respective portions. The different materials and/or coating may provide different electrical charge and entropy properties to the respective portions. Material having different heat conductivity characteristics, different heat absorption characteristics, different electrical charge characteristics, and different entropy characteristics for the first portion 66 and the second portion 68 may be selected such that the particles 28 exhibit positive thermodiffusion. Positive thermodiffusion propels the particles 28 to move from a relatively hotter region, such as the viscous sublayer 60, to a relatively colder region, such as the freestream 64.

The first portion 66 may absorb energy from the liquid 26 at a higher rate than the second portion 68, e.g., via conduction or convection. As another example, and without limitation, the first portion 66 may be less absorbent to radiant energy than the second portion 68, i.e., such that application of radiant energy to the particle 28 causes the second portion 68 to increase in temperature faster than the first portion 66. The first portion 66 and the second portion 68 may be on opposite sides, e.g., opposite halves, of the particle 28. For example, and without limitation, the first portion 66 may be on a first side 70 and the second portion 68 may be on a second side 72 opposite the first side 70. The first side 70 may include part, e.g., half, of an exterior surface of the particle 28 and generally face one direction, and the second side 72 include another part, e.g., the other half, of the exterior surface of the particle 28 and generally face an opposite direction.

The plurality of particles 28 may be configured to self-propel in response to receiving energy via conduction or convection. The material of the first portion 66 of each particle may absorb heat at a slower rate via conduction or convection and/or may require absorption of more heat via conduction or convection to increase in temperature relative to the material of the second portion 68.

During operation of the liquid thermal management system 32, the liquid 26 entering the cooler 22 has a lower temperature that the cooler 22. Heat may be transferred from the cooler 22 to the liquid 26 via conduction or convection from direct contact of the liquid 26 with the cooler 22. Such heat may be transferred from the liquid 26 to the particles 28 via conduction or convection from direct contact of the liquid 26 with the particles 28. Heat from the fluid transferred to the particles 28 via conduction or convection may increase a surface temperature of the first portion 66 slower than a surface temperature of the second portion 68 and cause the particle to self-propel within the fluid, e.g., via thermophoresis as discussed above.

The plurality of particles 28 may be configured to self-propel in response to receiving heat energy from the viscous sublayer 60. The material types, relative sizes, coating thicknesses, etc., of the first portion 66 and the second portion 68 may be selected such that a typical operation temperature of the liquid 26 in the viscous sublayer 60 is sufficient to induce self-propulsion of the particle, e.g., via thermophoresis and as discussed herein. The material types, relative sizes, coating thicknesses, etc., of the first portion 66 and the second portion 68 may be selected based on real-world testing and/or computer based simulation, e.g., indicating a temperature variance or gradient of the liquid 26 necessary for the particle to self-propel with the liquid 26.

The plurality of particles 28 may be configured to self-propel in response to receiving radiant energy. The material of the first portion 66 of each particle may absorb radiant energy at a slower rate and/or may require absorption of more radiant energy to increase temperature relative to the material of the second portion 68.

During operation, radiant energy may be applied to the particles 28 within the cooler 22, e.g., from the radiant energy emitter 58. The radiant energy may increase a surface temperature of the first portion 66 slower than a surface temperature of the second portion 68 and cause the particle to self-propel within the fluid, e.g., via thermophoresis as discussed above.

The particles 28 may each include a particle body 74. For example, and without limitation, the particle body 74 may be formed of silica. The particle body 74 may be generally spherical, or other suitable shape, for example, and without limitation, elliptical, hexagonal, octagonal, and/or the like. The particles 28 may each include a coating 76 on the first side 70 of the particle body 74. The coating 76 on the first side 70 may cover about half of the particle body 74. The coating 76 may provide an exterior surface of the particle 28 at the first side 70. The coating 76 may be gold, or other suitable material, for example and without limitation, silver, wax, nickel, titania, octadecyl trichlorosilane, aminopropyl-trimethoxysilane, etc. The second side 72 of the particle body 74 opposite the first side 70 may be free from having the coating 76. For example, the second side 72 of the particle body 74 may be free from having any coating thereon. In other words, the particle body 74 may provide the exterior surface of the particle 28 at the second side 72, i.e., such that the exterior surface of the particle 28 at the second side 28 is a same material as the particle body 74, e.g., silica. The silicon exterior surface of the second portion 68 may absorb heat energy, e.g., via convection or conduction, slower that the coating 76 on the first portion 66. As another example, the second side 72 may have a coating (not shown) that is other than the coating 76, i.e., having different thermal and/or other physical properties than the coating 76.

Alterative materials and/or dimensions for the first portion 66, the second portion 68, the particular body, and/or the coating may be selected, e.g., to enable the particle to self-propel in an operational environment. For example, and without limitation, materials of different densities, different radiant energy absorption characteristics, etc., may be selected based on a temperature of the fluid during operation of the component 30, an amount of radiant energy provided by the radiant energy emitter 58, etc. The different materials and designs for the particle may be selected based on real-world testing and/or computer based simulation.

It is noted that the terms “generally” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. An assembly for facilitating heat transfer, the assembly comprising:
a single-phase cooler having a liquid chamber with a plurality of micro-channels therein;
a liquid in the liquid chamber; and
a plurality of particles in the liquid, the plurality of particles configured to self-propel by thermophoresis such that the plurality of particles are self-propelled at a temperature difference between a free-flowing layer and a viscous sublayer of the liquid within the liquid chamber; and
wherein self-propelled movement of the plurality of particles mixes the liquid and causes the boundary between the free flowing layer and the viscous sublayer to be disrupted.

2. The assembly of claim 1, wherein the plurality of particles are configured to self-propel without a chemical reaction.

3. The assembly of claim 1, wherein the plurality of particles are configured to self-propel in response to receiving radiant energy.

4. The assembly of claim 3, further comprising a radiant energy emitter configured to emit radiant energy into the liquid chamber.

5. The assembly of claim 4, wherein the cooler includes a window and the radiant energy emitter is configured to emit radiant energy into the liquid chamber through the window.

6. The assembly of claim 1, wherein each particle of the plurality of particles includes a coating on a first side and each particle of the plurality of particles is free from having the coating on a second side opposite the first side.

7. An assembly for facilitating heat transfer, the assembly comprising:
a cooler having a liquid chamber;
a liquid in the liquid chamber; and
a plurality of particles in the liquid, the plurality of particles configured to self-propel within the liquid.

8. The assembly of claim 7, wherein the plurality of particles are configured to self-propel by thermophoresis such that the plurality of particles are self-propelled at a temperature difference between a free-flowing layer and a viscous sublayer of the liquid within the liquid chamber.

9. The assembly of claim 7, wherein the plurality of particles are configured to self-propel without a chemical reaction.

10. The assembly of claim 7, wherein the plurality of particles are configured to self-propel in response to receiving radiant energy.

11. The assembly of claim 10, further comprising a radiant energy emitter configured to emit radiant energy into the liquid chamber.

12. The assembly of claim 11, wherein the cooler includes a window and the radiant energy emitter configured to emit radiant energy into the liquid chamber through the window.

13. The assembly of claim 7, wherein liquid chamber includes micro-channels and the liquid with the plurality of particles therein is in the micro-channels.

14. The assembly of claim 7, wherein each particle of the plurality of particles includes a coating on a first side and each particle of the plurality of particles is free from having the coating on a second side opposite the first side.

15. The assembly of claim 14, wherein the coating is gold.

16. A system for facilitating heat transfer, the system comprising:
a pump;
a cooler having a liquid chamber fluidly coupled to the pump;
a liquid in the liquid chamber; and
a plurality of particles in the liquid, the plurality of particles configured to self-propel within the liquid.

17. The system of claim 16, further comprising a liquid reservoir fluidly coupled to the pump and the cooler.

18. The system of claim 16, further comprising a power electronics device thermally coupled to the cooler.

19. The system of claim 16, wherein each particle of the plurality of particles includes a coating on a first side and each particle of the plurality of particles is free from having the coating on a second side opposite the first side.

20. The system of claim 16, wherein the plurality of particles are configured to self-propel by thermophoresis such that the plurality of particles are self-propelled at a temperature difference between a free-flowing layer and a viscous sublayer of the liquid within the liquid chamber.
